(19) United States
(12) Patent Application Publication
(10) Pub. No.: US 2025/0028882 A1
(43) Pub. Date: Jan. 23, 2025

(54) TECHNIQUES FOR ENABLING CONVERSATIONAL USER INTERFACES FOR SIMULATION APPLICATIONS VIA LANGUAGE MODELS

(71) Applicant: AUTODESK, INC., San Francisco, CA (US)

(72) Inventors: Mohammadmehdi ATAEI, Toronto (CA); Hesam SALEHIPOUR, Richmond Hill (CA); Alexander TESSIER, Toronto (CA)

(21) Appl. No.: 18/750,783

(22) Filed: Jun. 21, 2024

Related U.S. Application Data
(60) Provisional application No. 63/514,061, filed on Jul. 17, 2023.
(60) Provisional application No. 63/514,063, filed on Jul. 17, 2023.

(51) Int. Cl. G06F 30/27; G06F 40/30; G06F 40/40; G06T 11/60

(52) U.S. Cl. CPC G06F 30/27; G06F 40/40; G06T 11/60; G06F 40/30

(57) ABSTRACT

One embodiment of a method for determining user intent includes receiving user input that comprises first natural language text, performing one or more operations to map the user input to one or more classes of intents included in a plurality of classes of intents, and responsive to determining that the user input does not map to any class of intents, generating, via a first trained language model, second natural language text requesting additional user input.

### CROSS-REFERENCE TO RELATED APPLICATIONS

This application claims priority benefit of the United States Provisional Patent Application titled, “TECHNIQUES FOR ENABLING CONVERSATIONAL USER INTERFACE FOR SIMULATION PLATFORMS VIA LARGE LANGUAGE MODELS,” filed on Jul. 17, 2023, and having Ser. No. 63/514,061, and the United States Provisional Patent Application titled, “TECHNIQUES FOR INTELLIGENT SIMULATION DATA ANALYSIS VIA MULTIMODAL LARGE LANGUAGE MODELS,” filed on Jul. 17, 2023, and having Ser. No. 63/514,063. The subject matter of these related applications is hereby incorporated herein by reference.

### BACKGROUND

### Field of the Various Embodiments

Embodiments of the present disclosure relate generally to artificial intelligence (AI), machine learning, and computer-based simulation and, more specifically, to techniques for enabling conversational user interfaces for simulation applications via language models.

### Description of the Related Art

Computer-based simulations use mathematical modeling, performed on computers, to simulate the behaviors and outcomes of real-world systems, such as physical systems. Computer-based simulations have applications in numerous fields, including fluid dynamics, structural mechanics, multi-physics, and systems modeling.

One conventional approach for performing a computer-based simulation requires a user to input a system or component to be modeled, as well as one or more goals of the simulation, such as the analysis or optimization of the system or component. One or more simulation models can then be executed based on the user input to generate simulation data. The user input is typically non-interactive and strictly formatted. Further, the user is oftentimes also required to specify the tools and parameters used to perform the simulation.

One drawback of the above approach is that user inputs are not typically checked for completeness or correctness. Incomplete or incorrect user inputs can result in errors during the configuration and/or execution of simulations, as well as in the analysis of data produced by the simulations. Accordingly, the above approach requires a high level of user proficiency in correctly specifying and executing simulations, and errors and inefficiencies can occur if the user input does not exactly match simulation requirements, either in content or in format.

As the foregoing illustrates, what is needed in the art are more effective techniques for performing computer-based simulations.

### SUMMARY

One embodiment sets forth a computer-implemented method for determining user intent. The method includes receiving user input that comprises first natural language text. The method further includes performing one or more operations to map the user input to one or more classes of intents included in a plurality of classes of intents. In addition, the method includes, responsive to determining that the user input does not map to any class of intents, generating, via a first trained language model, second natural language text requesting additional user input.

Another embodiment sets forth a computer-implemented method for performing a simulation. The method includes selecting a first data structure from a plurality of data structures based on a user input. The method further includes, responsive to determining that one or more values for one or more parameters specified in the first data structure cannot be determined based on the user input, generating, via a trained language model, first natural language text requesting additional user input. In addition, the method includes performing, based on the additional user input, a simulation to generate simulation data.

Another embodiment sets forth a computer-implemented method for analyzing data. The method includes determining, based on a first trained language model and a user request, one or more first functions. The method further includes executing the one or more first functions based on the data to generate first analysis data.

One technical advantage of the disclosed techniques relative to the prior art is that the disclosed techniques provide for interactive, natural-language interaction between a user and various components of a simulation application. The disclosed techniques iteratively engage with a user to determine the intent of a user request. The techniques further interact with the user via natural language to configure one or more simulation models and/or solvers prior to performing requested simulations. The techniques continue to interact with the user during the analysis of simulation data and can generate one or more reports based on the simulation data. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a computing device configured to implement one or more aspects of various embodiments.

FIG. 2 is more detailed illustration of the simulation application of FIG. 1, according to various embodiments.

FIG. 3 is a flow diagram of method steps for determining user intent for a simulation, executing one or more simulations, and analyzing simulation data, according to various embodiments.

FIG. 4 is a more detailed illustration of the intent engine of the simulation application of FIG. 1, according to various embodiments.

FIG. 5 is a flow diagram of method steps for determining user intent in a simulation application, according to various embodiments.

FIG. 6 is a more detailed illustration of the simulation engine of the simulation application of FIG. 1, according to various embodiments.

FIG. 7 is a block diagram of a function schema generator included in the simulation application of FIG. 2, according to various embodiments.

FIG. 8 illustrates an exemplar predefined data structure for a simulation model, according to various embodiments.

FIG. 9 is a flow diagram of method steps for configuring and executing one or more simulations in a simulation application, according to various embodiments.

FIG. 10 is a more detailed illustration of the analysis engine of FIG. 1, according to various embodiments.

FIG. 11 is a flow diagram of method steps for analyzing simulation data in a simulation application, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

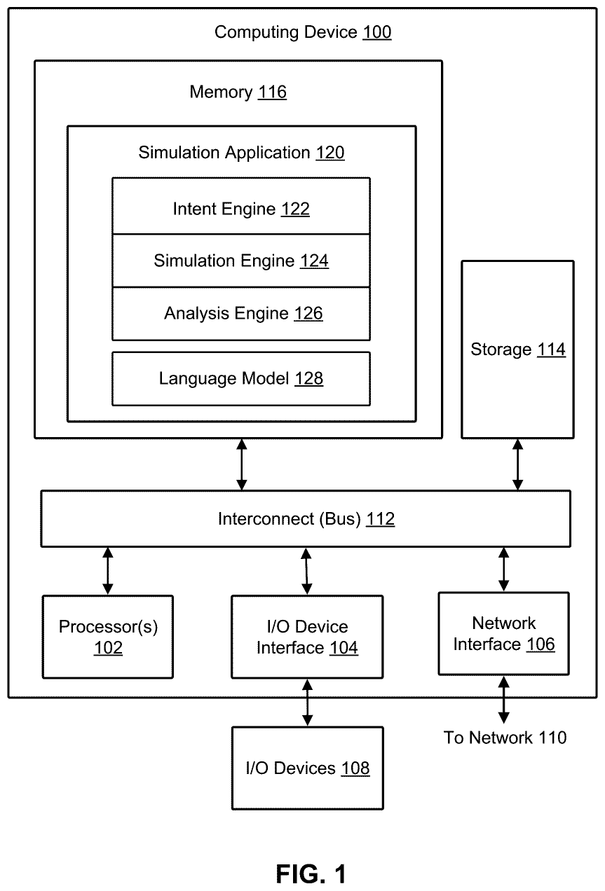

FIG. 1 illustrates a computing device 100 configured to implement one or more aspects of various embodiments. As shown, computing device 100 includes, without limitation, an interconnect (bus) 112 that connects one or more processors 102, an input/output (I/O) device interface 104 coupled to one or more input/output (I/O) devices 108, a memory 116, a storage 114, and a network interface 106. In some embodiments, computing device 100 can be a desktop computer, a laptop computer, a smart phone, a personal digital assistant (PDA), tablet computer, or any other type of computing device configured to receive input, process data, and optionally display images, and is suitable for practicing one or more embodiments. Illustratively, computing device 100 is configured to run a simulation application 120 that includes an intent engine 122, a simulation engine 124, an analysis engine 126, and a language model 128. In operation, simulation application 120 resides in memory 116 and executes on processor(s) 102 of computing device 100. In various embodiments, language model 128 can include a single language model, multiple different language models, or multiple instances of the same language model. Although shown as residing in memory 116 of computing device 100 for illustrative purposes, in some embodiments, language model 128 can reside in a different location, such as a cloud computing environment from which language model 128 is accessed by simulation application 120 via an application programming interface (API).

It is noted that the computing device described herein is illustrative and that any other technically feasible configurations fall within the scope of the present disclosure. For example, in some embodiments, any combination of the components in computing device 100 (e.g., process(s) 102, memory 116, etc.) can be replaced with components within any type of virtual computing system, distributed computing system, or cloud computing environment, such as a public cloud, a private cloud, or a hybrid cloud. In such cases, one or more instances of simulation application 120, intent engine 122, simulation engine 124, analysis engine 126, and/or language model 128 could execute on a set of nodes in the virtual computing system, distributed computing system, or cloud computing environment to implement the functionality of computing device 100. As another example, in some embodiments, simulation application 120, intent engine 122, simulation engine 124, analysis engine 126, and/or language model 128 can execute on various sets of hardware, types of devices, or environments to adapt simulation application 120, intent engine 122, simulation engine 124, analysis engine 126, and/or language model 128 to different use cases or applications. As a further example, in some embodiments, simulation application 120, intent engine 122, simulation engine 124, analysis engine 126, and/or language model 128 can execute on different computing devices and/or different sets of computing devices.

Illustratively, computing device 100 includes, without limitation, an interconnect (bus) 112 that connects one or more processors 102, an input/output (I/O) device interface 104 coupled to one or more input/output (I/O) devices 108, memory 116, a storage 114, and a network interface 106. Processor(s) 102 may be any suitable processor implemented as a central processing unit (CPU), a graphics processing unit (GPU), an application-specific integrated circuit (ASIC), a field programmable gate array (FPGA), an artificial intelligence (AI) accelerator, any other type of processing unit, or a combination of different processing units, such as a CPU configured to operate in conjunction with a GPU. In general, processor(s) 102 may be any technically feasible hardware unit capable of processing data and/or executing software applications. Further, in the context of this disclosure, the computing elements shown in computing device 100 may correspond to a physical computing system (e.g., a system in a data center) or may be a virtual computing instance executing within a computing cloud.

I/O devices 108 include devices capable of providing input, such as a keyboard, a mouse, a touch-sensitive screen, and so forth, as well as devices capable of providing output, such as a display device. Additionally, I/O devices 108 may include devices capable of both receiving input and providing output, such as a touchscreen, a universal serial bus (USB) port, and so forth. I/O devices 108 may be configured to receive various types of input from an end-user (e., a designer) of computing device 100, and to also provide various types of output to the end-user of computing device 100, such as displayed digital images or digital videos or text. In some embodiments, one or more of I/O devices 108 are configured to couple computing device 100 to a network 110.

Network 110 is any technically feasible type of communications network that allows data to be exchanged between computing device 100 and external entities or devices, such as a web server or another networked computing device. For example, network 110 may include a wide area network (WAN), a local area network (LAN), a wireless (WiFi) network, and/or the Internet, among others.

Storage 114 includes non-volatile storage for applications and data, and may include fixed or removable disk drives, flash memory devices, and CD-ROM, DVD-ROM, Blu-Ray, HD-DVD, or other magnetic, optical, or solid-state storage devices. Simulation application 120 can be stored in storage 114 and loaded into memory 116 when executed.

Memory 116 includes a random-access memory (RAM) module, a flash memory unit, or any other type of memory unit or combination thereof. Processor(s) 102, I/O device interface 104, and network interface 106 are configured to read data from and write data to memory 116. Memory 116 includes various software programs that can be executed by processor(s) 102 and application data associated with said software programs, including simulation application 120.

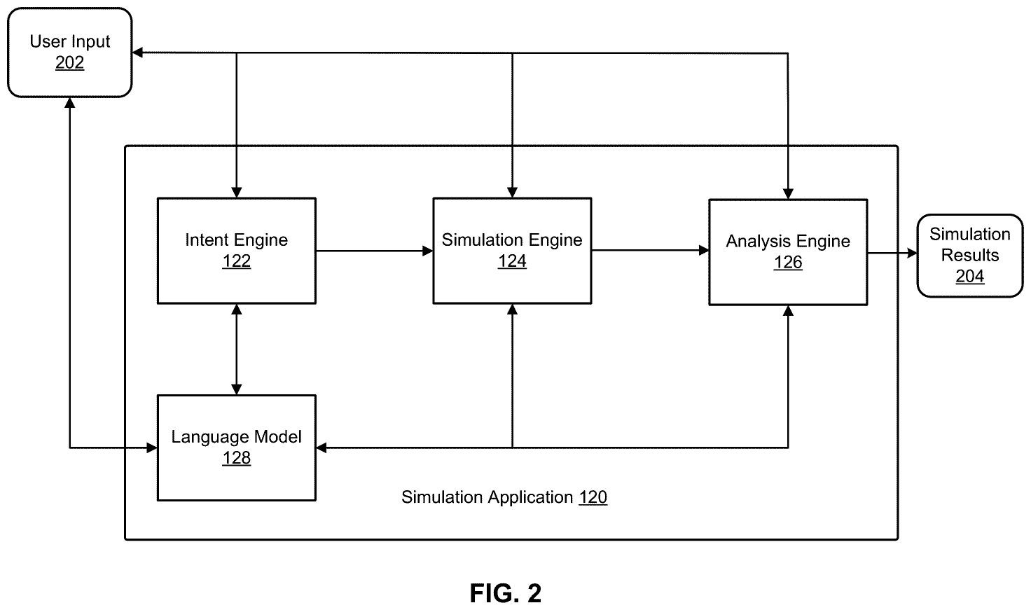

As discussed in greater detail below in conjunction with FIGS. 2-11, simulation application 120 is configured to receive natural language requests and perform computer-based simulations in response to the requests. In some embodiments, intent engine 122 processes user requests to determine intents, simulation engine 124 configures and executes one or more computer-based simulations, and analysis engine 126 analyzes simulation data produced by simulation engine 124 and generates summaries and reports for display to users.

### Enabling Conversational User Interfaces for Simulation Applications Via Language Models

FIG. 2 is a more detailed illustration of simulation application 120 of FIG. 1, according to various embodiments. As shown, simulation application 120 includes intent engine 122, simulation engine 124, analysis engine 126, and language model 128. In operation, simulation application 120 receives user input 202, determines a user intent for one or more computer-based simulations, configures and executes one or more computer-based simulations, and outputs simulation results 204 that can include, e.g., a summary of the simulation data, a report based on analysis of the simulation, and/or the like.

User input 202 includes natural-language text input received from a user (e., an analyst). In some embodiments, user input 202 can include an initial input from a user, such as “I would like to analyze the efficiency of a valve,” and (optionally) additional input from the user in response to one or more requests from simulation application 120 for additional information. Various components of simulation application 120, including intent engine 122, simulation engine 124, analysis engine 126, and/or language model 128, can process one or more portions of user input 202.

Language model 128 is a machine learning model that has been trained on a corpus of training data. Language model 128 can have any suitable architecture and be trained in any technically feasible manner in some embodiments. For example, in some embodiments language model 128 can include an artificial neural network, such as a large language model, a small language model, or the like. In some embodiments, language model 128 can be fine-tuned on domain-specific training data after an initial training or, alternatively, may have received no additional training beyond the initial training. In some embodiments, language model 128 can include a single language model, a plurality of different language models, or multiple instances of a single language model.

Language model 128 processes natural-language user input during various phases of operation, described below in the discussions of intent engine 122, simulation engine 124, and analysis engine 126. Language model 128 can also process input from simulation application 120 regarding simulation capabilities of simulation application 120, including available simulation capabilities and requirements for various simulations. In some embodiments, language model 128 can perform function calls via one or more application program interfaces (APIs), select from available simulation tools, and/or generate computer code to implement simulation tools that are not already available to simulation application 120.

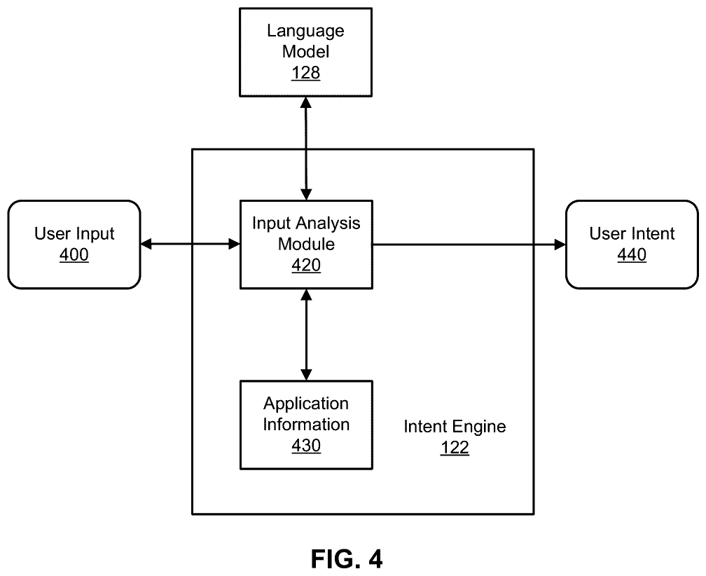

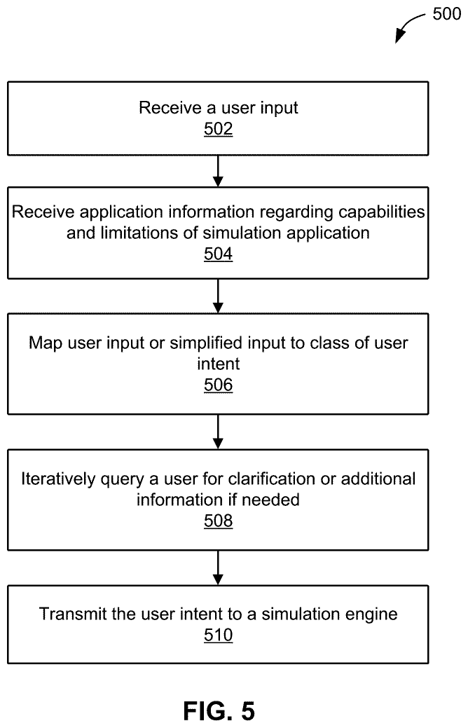

Intent engine 122 determines a user intent for a simulation based on one or more natural-language requests and/or responses received from the user via language model 128, egg., “I want to determine the pressure drop across a valve.” Intent engine 122 can also determine one or more appropriate simulation tasks based on the intent. For example, the simulation tasks could include fluid simulations, structural simulations, or fluid/structure interactions. In addition, intent engine 122 can determine one or more simulation tools, such as one or more solvers and/or simulation models, for performing the one or more simulation tasks. Intent engine 122 is discussed in greater detail below in conjunction with FIGS. 4-5.

Based on the determined solver(s) and/or simulation model(s), simulation engine 124 compares user input 202 to a predefined data structure associated with each solver or simulation model to determine whether the user has provided all necessary information to execute the solver(s) and/or simulation model(s), as indicated by the predefined data structures. If the user has not provided all necessary information, simulation engine 124 uses language model 128 to generate natural language text asking the user for additional information. Simulation engine 124 can also execute function calls to retrieve information from, e.g., a database, or request necessary APIs for one or more simulation tools. Simulation engine 124 continues to prompt the user and/or retrieve additional information via function calls until simulation engine 124 has received, or can infer, all of the necessary information to execute the one or more determined simulation solver(s) and/or simulation model(s). Thereafter, simulation engine 124 executes the solver(s) and/or simulation model(s).

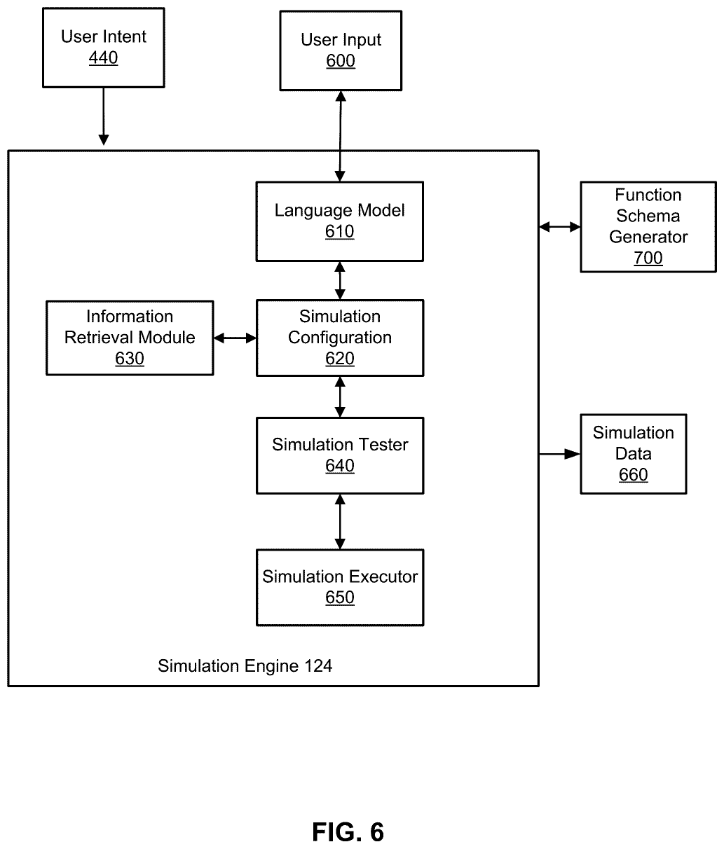

In some embodiments, simulation engine 124 first executes a test run of the solver(s) and/or simulation model(s). During the test run, simulation engine 124 can check for errors in the solver(s) and/or simulation model(s), such as syntax errors, rapid divergence in one or more simulation solutions, and/or excessive demands on computer hardware. If simulation engine 124 detects an error, simulation engine 124 determines whether the error can be corrected. If the error can be corrected, simulation engine 124 can prompt the user to change one or more parameters of the solver(s) and/or simulation model(s) to correct the error. Simulation engine 124 can execute multiple test runs and perform multiple adjustments to the solver(s) and/or simulation model(s) based on user input 202 until a test run executes successfully. Simulation engine 124 can then display finalized simulation parameters to the user and prompt the user to proceed with the execution of the solver(s) and/or simulation model(s). During execution of the one or more solver(s) and/or simulation model(s), simulation engine 124 can generate simulation data and display the progress of the execution to the user. At the conclusion of the execution, simulation engine 124 transmits the simulation data to analysis engine 126. Simulation engine 124 is discussed in greater detail below in conjunction with FIGS. 6-9.

Analysis engine 126 performs analysis on the simulation data received from simulation engine 124 and generates one or more reports (e., report 204) that display analysis results to the user. In operation, analysis engine 126 can receive user input 202 requesting a particular analysis. If the request is unclear, analysis engine 126 can use language model 128 to generate natural language text requesting further information from the user. Analysis engine 126 determines whether the nature of the analysis request is exploratory or if the analysis request necessitates a definitive analysis. In some embodiments, analysis engine 126 can determine the nature of the analysis request via a zero-shot classification technique or using language model 128.

Analysis engine 126 formulates a plan for analyzing the simulation data based on the nature of the analysis request. For example, if analysis engine 126 determines that the analysis request is exploratory, analysis engine 126 could generate an analysis plan including data exploration, cluster analysis, outlier detection, and/or pattern recognition. As another example, if the analysis request requires a definitive analysis, the analysis engine 126 could generate an analysis plan that includes specific statistical tests to validate one or more hypotheses, predictive modeling to anticipate future trends, or designing detailed, specific visual plots to illustrate specific points. A definitive analysis plan can focus on drawing clear and explicit conclusions from the simulation data to address a specific user objective.

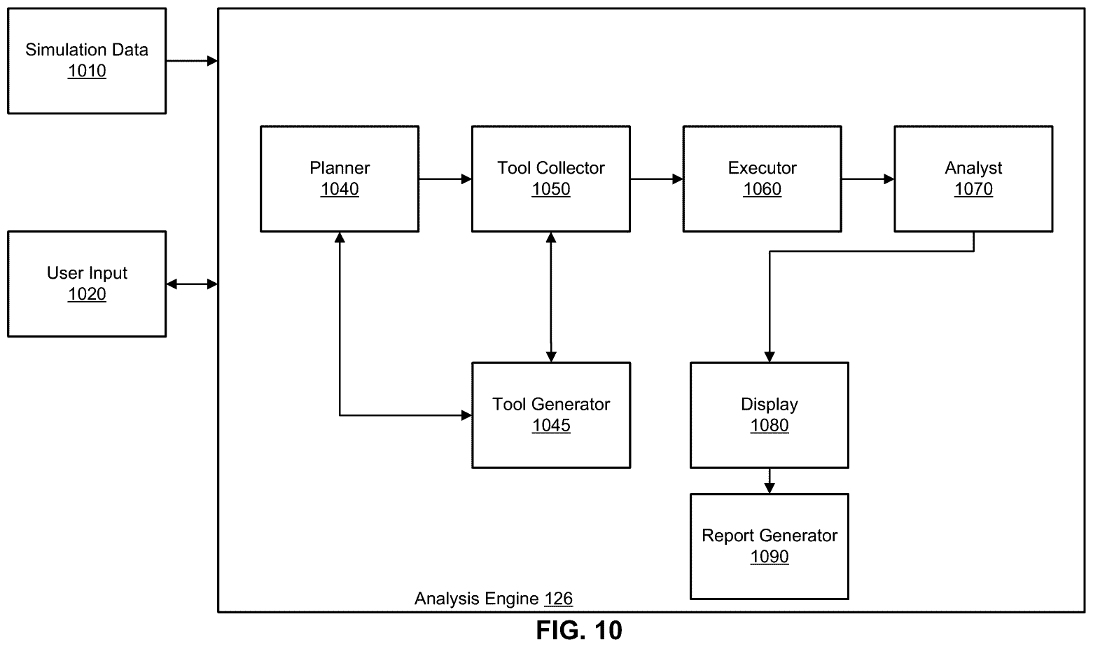

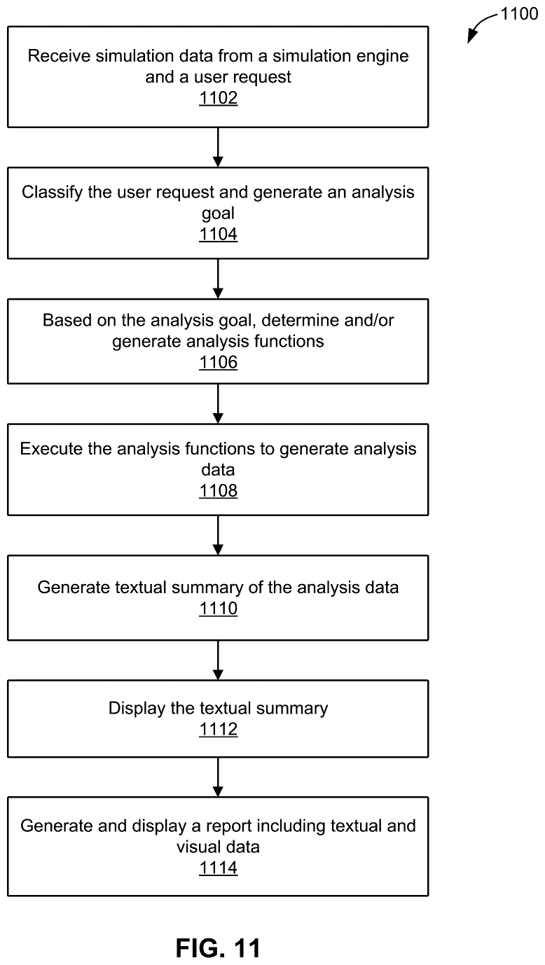

In some embodiments, analysis engine 126 also confirms the availability of needed functions such as visualizers, plotters, classifiers, and/or statistical analysis toolsets. If a required function or toolset is missing, analysis engine 126 can use language model 128 to generate program code for implementing the missing function or toolset. If analysis engine 126 is unable to generate a required function or toolset, analysis engine 126 can adapt the analysis plan by either selecting an alternative technique for achieving an analysis goal or adjusting the analysis plan to remove the requirement for the missing function or toolset. Analysis engine 126 then executes function calls associated with the functions and/or toolsets to process the simulation data. Following the execution of the function calls, analysis engine 126 generates and displays a textual summary of the data generated by the outputs of the function calls. The summary can provide a concise and informative overview of the generated data. If the outputs of the function calls include visual elements such as images, video, or time-varying n-dimensional data formats, analysis engine 126 can store such visual outputs and make the outputs available for subsequent processes. Analysis engine 126 can also add the location of the stored visual outputs to the textual summary. In some embodiments, analysis engine 126 can also evaluate the data generated by the outputs of the function calls in order to extract meaningful insights, trends, and/or patterns within the generated data. In such cases, analysis engine 126 interprets the results and generates conclusions based on the user analysis request and explains the significance of the findings. Then, analysis engine 126 displays the generated visual data to the user via one or more interactive user interfaces (UIs), highlighting relevant locations in the visual data based on the conclusions. The generated visual data corresponds to and supports the displayed textual data, described above. In addition, analysis engine 126 can compile a report detailing the findings and conclusions of the analysis, as well as interpretations and implications of the analysis. For example, the report could include both textual and visual data analytics. Analysis engine 126 is described in greater detail below in conjunction with FIGS. 10-11.

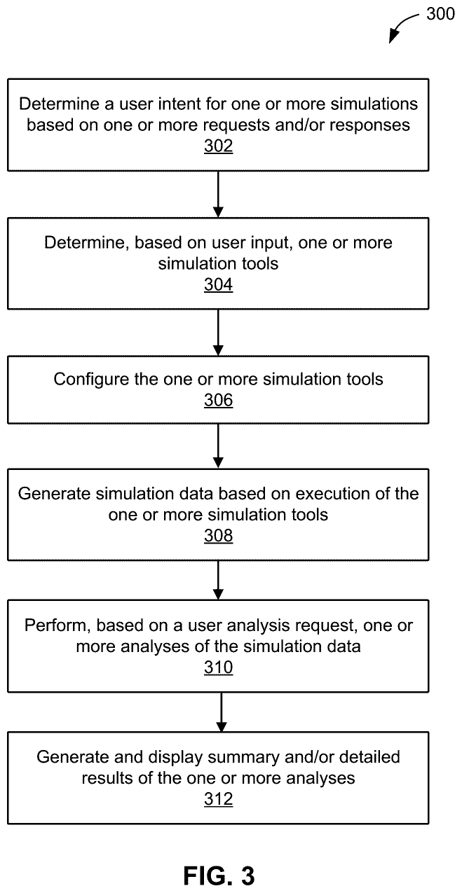

FIG. 3 is a flow diagram of method steps for determining user intent for a simulation, executing one or more simulations, and analyzing simulation data, according to various embodiments. Although the method steps are described in conjunction with the systems of FIGS. 1-2, persons skilled in the art will understand that any system configured to perform the method steps in any order falls within the scope of the present disclosure.

As shown, a method 300 begins at operation 302, where intent engine 122 of simulation application 120 determines a user intent for a simulation based on one or more natural-language requests from the user and/or responses from the user to prompts by simulation application 120. In some embodiments, the natural-language request(s) and/or response(s) can be received in any technically feasible manner, such as via a UI. Given the natural language request(s) and/or response(s), the intent can be determined by mapping the user request one of a number of classes of problems to solve, such as using a zero-shot classification technique or using a prompt asking language model 128 to determine the class of the problem, as discussed in greater detail below.

At operation 304, simulation engine 124 of simulation application 120 determines one or more appropriate simulation tools, such as solvers and/or simulation models, based on user input. In some embodiments, simulation engine 124 can determine the appropriate simulation tools based on an initial user request, and/or simulation engine 124 can iteratively prompt the user for additional information that is required. Then, simulation engine 124 can select one or more simulation tools based on the initial user request and/or the additional information. In addition, simulation engine 124 can provide follow-on prompts to the user to confirm the one or more selected simulation tools, as discussed in greater detail below in conjunction with FIGS. 5-9.

At operation 306, simulation engine 124 configures the one or more simulation tools for execution. In some embodiments, simulation engine 124 determines whether all necessary information has either been provided by the user or can be inferred by simulation engine 124. For example, in some embodiments, simulation engine 124 can fulfill the requirements of a simulation tool by asking the user to provide necessary parameters such as properties or geometries, via a system request for a necessary API, and/or by comparing gathered information to a script or compiled code, as discussed in greater detail below in conjunction with FIGS. 5-9.

At operation 308, simulation engine 124 executes the simulation tool(s). In various embodiments, simulation engine 124 can first execute a test run of the simulation tool(s), which can include one or more solvers and/or simulation models. During the test run, simulation engine 124 checks for errors in the simulation tool(s) and determines whether the errors can be corrected. If the errors can be corrected, simulation engine 124 can prompt the user to change one or more parameters of the simulation tool(s) to correct the errors. Simulation engine 124 can also display finalized simulation parameters to the user and prompt the user to confirm proceeding with execution of the simulation tool(s). During execution of the simulation tool(s), simulation engine 124 can generate simulation data and display the progress of the execution to the user. After executing the simulation tool(s), simulation engine 124 transmits the simulation data to analysis engine 126.

At operation 310, analysis engine 126 performs, based on a user analysis request, one or more analyses of the simulation data. In some embodiments, analysis engine 126 can perform analysis on the simulation data, display results of the analysis to the user, and/or generate one or more reports based on analysis of the simulation data. As described, analysis engine 126 can determine whether the nature of the analysis request is exploratory or if the analysis request necessitates a definitive analysis. Analysis engine 126 can then initiate a review to confirm the availability of required functions such as visualizers, plotters, classifiers, or statistical analysis toolsets. If a required function or toolset is missing, analysis engine 126 can use language model 128 to generate the necessary program code for implementing the missing function or toolset. If analysis engine 126 is unable to generate a required function or toolset, analysis engine 126 can adapt the analysis plan, either by selecting an alternative technique for achieving an analysis goal or adjusting the analysis plan to remove the requirement for the missing function or toolset. Analysis engine 126 then executes function calls associated with the essential functions and toolsets to process the simulation data.

At operation 312, analysis engine 126 generates and displays a summary and/or detailed results of the one or more analyses. In some embodiments, analysis engine 126 generates and displays a textual summary of data generated as a result of the function calls at operation 310. In such cases, the summary can provide a concise and informative overview of the generated data. Analysis engine 126 can further perform a detailed examination of the generated data in some embodiments. In some embodiments, analysis engine 126 evaluates the data generated as a result of the function calls, extracting meaningful insights, trends, and/or patterns within the generated data. In some embodiments, analysis engine 126 interprets the results and generates conclusions based on the user analysis request and explains the significance of the findings. In some embodiments, analysis engine 126 can generate and display visual data to the user via one or more interactive visualizations, highlighting relevant locations in the visual data based on the conclusions. In such cases, the generated visual data corresponds to and supports the displayed textual data described above. In some embodiments, analysis engine 126 can generate and display a report detailing the findings and conclusions of the analysis, as well as interpretations and implications of the analysis. In such cases, the report can include both textual and visual data analytics.

### Capturing User Intent

FIG. 4 is a more detailed illustration of intent engine 122 of simulation application 120, according to various embodiments. As shown, intent engine 122 includes an input analysis module 420 and application information 430. In operation, intent engine 122 determines a user intent for a simulation based on one or more natural-language requests and/or responses received in user input 400 and determines one or more appropriate simulation tasks based on user input 400.

User input 400 can include an initial request from a user via a conversational user interface (CUI), or a request from an upstream software application. In some embodiments, user input 400 can include natural language questions or statements, such as “I would like to find out if this valve has a pressure drop of less than five psi, at a water flow rate of twenty gallons per minute.” For example, user input 400 could include inquiries regarding the capabilities of simulation application 120 or of a specific simulation tool, such as a solver. User input 400 can also include user responses to clarifying queries from input analysis module 420, as described below.

Intent engine 122 transmits user input 400 for processing by language model 128 to generate a simplified input. Language model 128 receives user input 400 and interprets and transforms the user input to generate the simplified input, which can be a clearer, shorter, and/or more coherent version of a request in user input 400. In some embodiments, intent engine 122 can enhance the context of language model 128 via knowledge retrieval. In knowledge retrieval, the various components of simulation application 120 can execute function calls selected from a function schema database to incorporate specific, relevant contextual information into language model 128 as a pre-prompt.

Language model 128 transmits the simplified input to input analysis module 420. Language model 128 can also communicate with input analysis module 420 to generate natural language text asking the user for additional input that may be required, such as if user input 400 is unclear and input analysis module 420 cannot determine a user intent from user input 400.

Input analysis module 420 receives the simplified input generated by language model 128 and maps the simplified input (or the original user input 400) to an intent. For example, input analysis module 420 can determine if the simplified input is a general query regarding available simulations, a request to run a specific type of simulation, a request to perform an optimization problem, a request for clarification of a particular simulation tool such as a solver, or a request regarding the general capabilities, functionalities, or limitations of simulation application 120.

In some embodiments, input analysis module 420 can map the simplified input to user intent 400 using a zero-shot classification model (“zero-shot classifier”) that is included in input analysis module 420, or that input analysis module 420 has access to. In some embodiments, the zero-shot classifier includes a set of classes, with each class representing a particular type of request. Each class includes a detailed textual description of the class. Input analysis module 420 generates vector embeddings for each class included in the zero-shot classifier based on the textual descriptions associated with the classes. Input analysis module 420 also generates a vector embedding based on the simplified user input received from language model 128. Input analysis module 420 determines a similarity between the simplified user input vector embedding and each of the vector embeddings associated with classes in the zero-shot classifier. Any technically feasible similarity metric, such as cosine similarity, can be used in some embodiments. Based on the similarities, input analysis module 420 generates a probability distribution over the classes in the zero-shot classifier and identifies the class having the highest probability as the most likely class to correspond to the user request. Input analysis module 420 can also generate an uncertainty value for the classification based on the entropy of the generated probability distribution.

In some embodiments, input analysis module 420 can map the simplified input to user intent 440 through a chain-of-thought technique. In such cases, input analysis module 420 retrieves an initial system message from application information 430 that includes details about the capabilities and functionalities of simulation application 120. Application information 430 can include a general description of simulation application 120 and details regarding specific simulation tools available in simulation application 120. Input analysis engine 420 transmits the initial system message to language model 128, and language model 128 incorporates the initial system message as a pre-prompt that provides additional language model context about the classes of intents that the simplified input can map to. Input analysis module 420 determines a user intent and an uncertainty value by inputting the user input 400 and the additional context, along with a request asking for the user intent and an uncertainty, into language model 128. More specifically, in the chain-of-thought technique, the request to language model 128 can break down the complex problem or query of determining the user intent into a sequence of intermediate steps or thoughts, thereby helping language model 128 to follow a logical progression and enhances its reasoning capabilities, leading to more accurate responses. Accordingly, chain-of-thought can enhance the performance of language model 128 by providing a structured reasoning path, although chain-of-thought is not specifically required for zero-shot classification. In some embodiments, language model 128 can output a probability distribution over possible user intents, from which, e.g., an entropy value (or other uncertainty quantifications) can be calculated to quantify uncertainty. Additionally, in some embodiments, zero-shot classification using language model 128 can be greedy, in which case language model 128 can select the most likely class based on the highest probability.

Based on the uncertainty value generated by the zero-shot classifier or the chain-of-thought technique (or another text classification technique for determining uncertainty and user intent), input analysis module 420 determines if the user intent is sufficiently clear to proceed to simulation setup in simulation engine 124, described in conjunction with FIGS. 5-6. If the uncertainty exceeds a threshold, input analysis module 420 will attempt to clarify the user intent through interaction with the user via language model 128. Input analysis module 420 can request, via natural language text generated using language model 128, that the user better formulate the problem, or confirm an interpreted intent generated by input analysis module 420. For example, if a user uploads a file describing the structure of a pipe with no additional context, input analysis module 420 can infer that the user intends to run a fluid dynamics simulation. Based on such an inference, input analysis module 420 can provide the user with information regarding the simulation application's capabilities to simulate fluid flow, propose a potential simulation scenario, and present the proposal to the user. Input analysis module 420 can query the user on whether to proceed with the proposed scenario or provide additional details. Input analysis module 420 can iteratively query the user until the calculated uncertainty value for the user intent is below a threshold value. Based on determining that the calculated uncertainty value is below a threshold, intent engine 122 stores the user intent as user intent 440. User intent 440 can include a general query from the user, such as a request regarding the capabilities of simulation application 120 or of a particular solver or simulation. User intent 440 can also include a request that simulation application 120 execute a simulation or optimization problem. Intent engine 122 then transmits user intent 440 to simulation engine 124.

In some other embodiments, intent engine 122 can map user input 400 and/or a simplified input generated using language model 120 to user intent 440 in any technically feasible manner. For example, in some embodiments, intent engine 122 can map user input 400 or the simplified input to user intent 440 using a predefined data structure that specifies definite class options that the user intent can include, providing a format that needs to be adhered to given the simulation capabilities of simulation application 120. In such cases, intent engine 122 can check (e.g., via a script) whether user input 400 matches one of the definite options for user intents in the predefined data structure. If the input 400 does not match any of the definite options, then an error occurs that can be fixed by using language model 128 to generate natural language text asking the user for additional input, until the user input matches one of the definite options in the predefined data structure. As another example, in some embodiments, intent engine 122 can map user input 400 or the simplified input to user intent 440 using a language model that is fine tuned to output classes of requests. As yet another example, in some embodiments, intent engine 122 can map user input 400 or the simplified input to user intent 440 with an associated uncertainty using any technically feasible text classification technique.

FIG. 5 is a flow diagram of method steps for determining user intent in a simulation application, according to various embodiments. Although the method steps are described in conjunction with the systems of FIGS. 1-4, persons skilled in the art will understand that any system configured to perform the method steps in any order falls within the scope of the present disclosure.

As shown, a method 500 begins at operation 502, where intent engine 122 receives a user input. For example, the user input can be natural language text that includes a general inquiry regarding the capabilities of the simulation application or of a particular simulation tool, or that includes a request to run a particular type of simulation or optimization problem.

At operation 504, intent engine 122 receives an initial system message from application information 430. The initial system message includes general information regarding simulation application 120 and detailed information regarding the simulation tools available to the platform, including available simulation and optimization capabilities. Intent engine 122 can transmit the information included in the initial system message to language model 128 as a pre-prompt to provide additional contextual information to language model 128.

At operation 506, intent engine 122 maps the user input or a simplified input generated from the user input to a class of user intent. In some embodiments, intent engine 122 can generate the simplified user input using language model 128 and map the simplified user input to the user intent via a one-shot classifier or a chain-of-thought technique using the application information 430 received at operation 504. In such cases, intent engine 122 can further generate an uncertainty value associated with the determined user intent, as described above in conjunction with FIG. 4. In some other embodiments, intent engine 122 can map the user input to a user intent using a predefined data structure that specifies definite class options by checking whether user input matches one of the options for user intents and, if the user input does not match one of the options, using language model 128 to generate natural language text asking the user for additional input, until the user input matches one of the options in the predefined data structure. In some embodiments, intent engine 122 can map the user input to a user intent using a fine-tuned language model that is trained to output classifications of intent. In some embodiments, intent engine 122 can map the user input or the simplified input to a user intent with an associated uncertainty using any technically feasible text classification technique.

At operation 508, intent engine 122 iteratively asks the user for more information if intent engine 122 does not successfully map the user input or simplified input to a user intent, such as if the uncertainty value associated with the determined intent is above a threshold or the user input does not match any option in a predefined data structure. In some embodiments, intent engine 122 can use language model 128 to generate natural language text requesting additional information from the user or for the user to confirm or reject a proposed user intent generated by intent engine 122. Intent engine 122 can continue to iteratively ask the user for more information until the user input and/or a simplified input is successfully mapped to a user intent.

At operation 510, intent engine 122 stores the user intent 440, including any user requests for information or clarification regarding simulation application 120 and any requests to perform simulation or optimization problems, and transmits user intent 440 to simulation engine 124.

### Simulation Configuration and Execution

FIG. 6 is a more detailed illustration of simulation engine 124 of FIG. 1, according to various embodiments. As shown, simulation engine 124 includes a language model 610, a simulation configuration module 620, an information retrieval module 630, a simulation tester 640, and a simulation executor 650. In operation, simulation engine 124 receives user intent 440 from intent engine 122 and selects one or more appropriate solvers for a query or simulation based on the user intent. Simulation engine 124 determines whether all necessary information to generate the response or configure the simulation is available and can request additional information from the user. Simulation engine 124 can also gather APIs or API calls necessary to perform a simulation. Simulation engine 124 generates a response to a user query and/or executes the configured simulation, as appropriate.

Simulation engine 124 receives user intent 440 from intent engine 122. As described above, user intent 400 can represent a query from a user regarding the capabilities of simulation application 120 or of a particular simulation tool, a request for a simulation or optimization, and/or the like.

Language model 610 can be a trained large language model in some embodiments. In some embodiments, language model 610 can be the same large language model as language model 128, described above. In other embodiments, language model 610 can be a different large language model than language model 128, or can be a separate instance of the same large language model.

Simulation engine 124 transmits user intent 440 to language model 610 and determines, using language model 610, a set of simulation tools required to satisfy user intent 440. A simulation tool can enable simulation engine 124 to respond to a user request for information or clarification regarding simulation application 120, or can include a particular solver or simulation model.

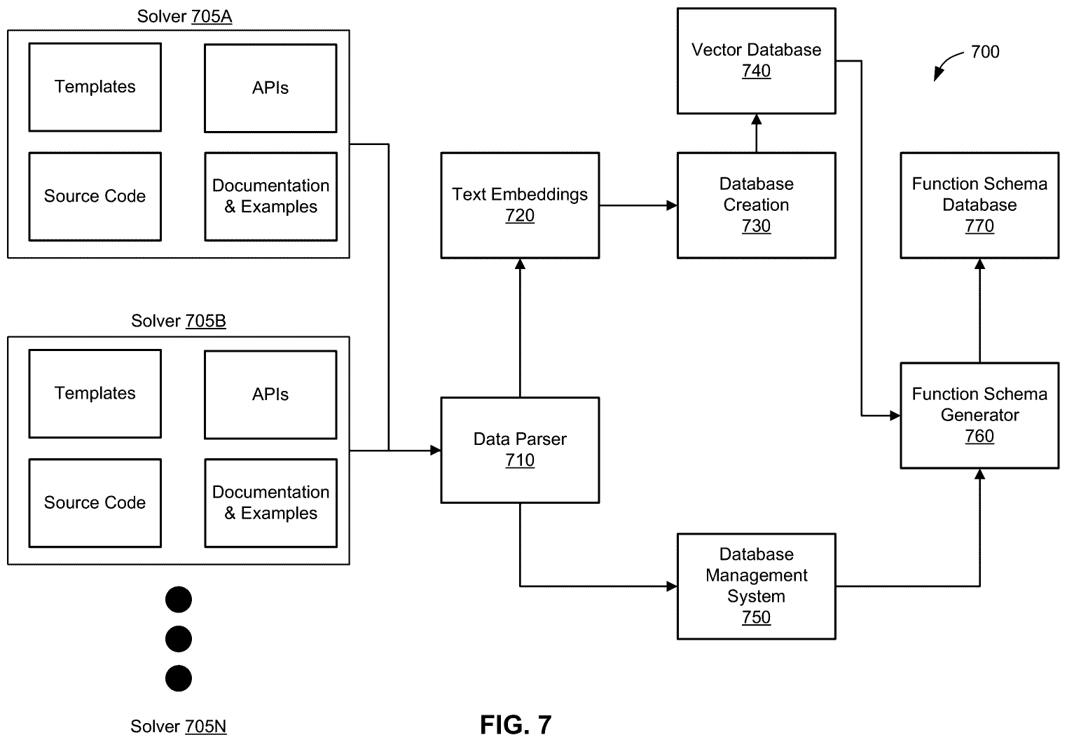

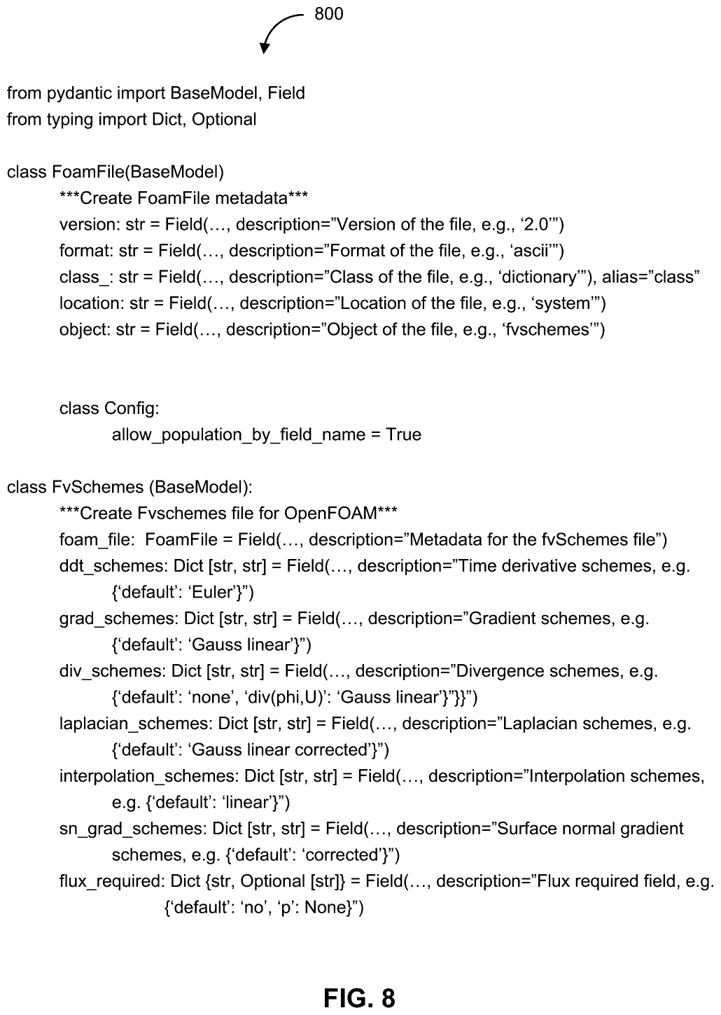

For each simulation tool in the set of simulation tools, simulation engine 124 determines information necessary for execution of the simulation tool. In some embodiments, simulation configuration module 620 can request a function schema associated with the simulation tool from function schema generator 700. A function schema includes a template that specifies, e.g., parameters for the simulation tool, necessary inputs for the simulation tool, and/or default values for variables included in the simulation tool. Function schemas are discussed in more detail below in conjunction with FIGS. 7-8.

Simulation configuration module 620 parses the function schema received from function schema generator 700 and generates one or more function calls based on information included in the function schema. Simulation configuration module 620 transmits the function calls to information retrieval model 630 for execution. In various embodiments, a function call can specify an element of information necessary to execute a simulation tool or to respond to a user query.

Information retrieval module 630 receives a function call from simulation configuration module 620. Information retrieval module 630 transmits the function call to function schema generator 700 via language model 610. Information retrieval module 630 receives the necessary information from function schema generator 700 and transmits the information to language model 610 as a pre-prompt. The pre-prompt provides additional context to language model 610. In various embodiments, information retrieval module 630 can summarize the information received from function schema generator 700 based on an allowable context or prompt size for language model 610. In various embodiments, information retrieval module 630 can request and receive functions, APIs, source code, examples, templates, documentation, and definitions associated with one or more simulation tools.

Simulation configuration module 620 can determine, based on user intent 440, that additional information is required from the user. Simulation configuration module 620 can interact with the user via language model 610, which can be used to generate natural language text requesting additional information from the user.

Simulation configuration module 620 can also determine, based on user intent 440, that simulation engine 124 requires one or more APIs for the execution of a simulation tool. In such cases, simulation configuration module 620 transmits a description of a requested API to information retrieval module 630, which requests and receives the required API from, e.g., function schema generator 700 or elsewhere.

After simulation engine 124 determines that simulation configuration module 620 has gathered all necessary additional information, simulation engine 124 determines whether it is necessary to execute a simulation. For example, based on user intent 440, simulation engine 124 can determine that the user intent represents a general user query regarding the capabilities of simulation application 120, and that it is not necessary to execute a simulation. In such cases, simulation engine 124 can use language model 610 to respond to the user query based on the information retrieved by information retrieval modules 630.

If simulation engine 124 determines to execute a simulation, simulation tester 640 generates and executes a test run of the simulation. In some embodiments, the test run of the simulation can include a limited quantity of data to be analyzed or can execute the simulation for a limited period of time or for a specified number of iterations. Simulation tester 640 monitors the test run of the simulation and analyzes the execution for errors. Errors can include syntax errors in the simulation tool, or a runtime error such as a division by zero error or an out-of-bounds error. Other errors can include a simulation solution that rapidly diverges during the test run, or excessive consumption of one or more system resources such as memory or CPU cycles. If simulation engine 124 detects an error during simulation 640, simulation engine 124 can attempt to diagnose and correct the error automatically, or can prompt the user via language model 610 to modify one or more parameters of the simulation to address the error. Simulation tester 640 can iteratively modify the parameters of the simulation and execute additional test runs until a test run executes without errors.

At the conclusion of a successful test run, simulation tester 640 can present a finalized simulation configuration to the user and request confirmation from the user before executing the simulation. Upon user approval, simulation executor 650 performs a full execution of the simulation and displays a progress indication to the user. Simulation engine 124 generates simulation data 660 based on the execution of the simulation, and transmits simulation data 660 to analysis engine 126, described below in greater detail in conjunction with FIGS. 10-11.

FIG. 7 is a block diagram of function schema generator 700 in simulation application 120 of FIG. 2, according to various embodiments. As shown, function schema generator 700 creates a database 770 of function schemas, with each schema including information associated with a simulation tool such as a solver or simulation. Each schema can also include variables or parameters necessary to execute a simulation tool. Function schema generator 700 further includes a vector database 740 of information associated with various solvers. For a particular solver, vector database 740 can store associated templates, APIs, source code, documentation, and/or examples. Function schema generator 700 can respond to requests from information retrieval module 630 described above for information associated with a particular solver or other simulation tool. Function schema generator 700 also includes, without limitation, solvers 705A-N, data parser 710, text embedding module 720, database creation 730, function schema generator 760, and function schema database 770.

Each of solvers 705A-N includes information associated with a particular simulation tool, such as a fluid dynamics simulator or a structural simulator. Information associated with each of solvers 705A-N can include templates describing variables associated with the solver or source code for the solver, if available. The information associated with a solver can also include one or more APIs allowing other system components to interface with or query the solver, as well as documentation and examples associated with the solver. When a new solver is added to function schema generator 700 or an existing solver is removed from function schema generator 700, simulation application 120 re-instantiates function schema generator 700 to process the updated set of solvers 705A-N.

Data parser 710 retrieves information associated with each of solvers 705A-N such as the templates, APIs, source code, documentation, and/or examples discussed above. In some embodiments, data parser 710 can summarize, condense or otherwise process information associated with each of solvers 705A-N. Data parser 710 transmits the processed information to text embedding module 720 and database management system 750.

Text embedding module 720 analyzes the processed information associated with solvers 705A-N received from data parser 710. Based on the analysis, text embedding module 720 generates vector embeddings associated with one or more of the elements of solver information. Text embedding module 720 transmits the vector embeddings to database creation 730 for inclusion in vector database 740. Vector database 740 stores the vector embeddings of information associated with each of solvers 705A-N. Vector database 740 can further store vector embeddings generated from user interactions performed by simulation application 120 and simulation results generated by simulation engine 124. Function schema generator 700 can transmit the stored vector embeddings generated from previous user interactions and executed simulations to various large language models to provide additional context to the various large language models during subsequent user interactions and/or simulation executions.

Database management system 750 manages the data and database schemas of vector database 740 and function schema database 770, allowing for data to be manipulated or extracted by the various components of simulation application 120.

In some embodiments, a function schema is a data structure defining inputs required for a simulation tool, such as a simulation model or solver. A function schema can also include parameters and/or variables for the simulation tool. In some embodiments, function schemas can include definite options that, if not selected by a user, result in an error that a language model asks the user to correct (e.g., by calling a function) in a chain-of-thought manner, until the function schema data structure has been filled out with acceptable inputs. In such cases, a function schema can confine the output generated using the language model to the format specified in the function schema. An example of a function schema is depicted in FIG. 8. Function schemas can be defined manually and/or automatically generated in some embodiments. In some embodiments, function schema generator 760 can use a language model (e.g., language model 128) to generate one or more function schemas based on capabilities of simulation models and/or solvers and templates for creating function schemas. The capabilities of simulation models and/or solvers can be input by a user or automatically determined, such as by parsing documentation about the simulation models and/or solvers that function schema generator 700 retrieves from vector database 740. Illustratively, function schema generator 700 stores generated function schemas in function schema database 770 for subsequent retrieval and use by components of simulation application 120. Function schema database 770 can be any technically feasible type of database in some embodiments. For example, in some embodiments, function schema database 770 can be a vector database, and user inputs can be summarized and an embedding search performed by comparing embeddings of the summarized user inputs and embeddings of descriptions of the function schemas, such as comments about classes therein, in order to determine relevant function schemas for performing simulations for the user inputs.

FIG. 8 illustrates an exemplar function schema 800 for a simulation model, according to various embodiments. As shown, function schema 800 includes information associated with an OpenFOAM computational fluid dynamics model. In particular, function schema 800 includes class and scheme information for the model, as well as metadata indicating textual descriptions for various input fields.

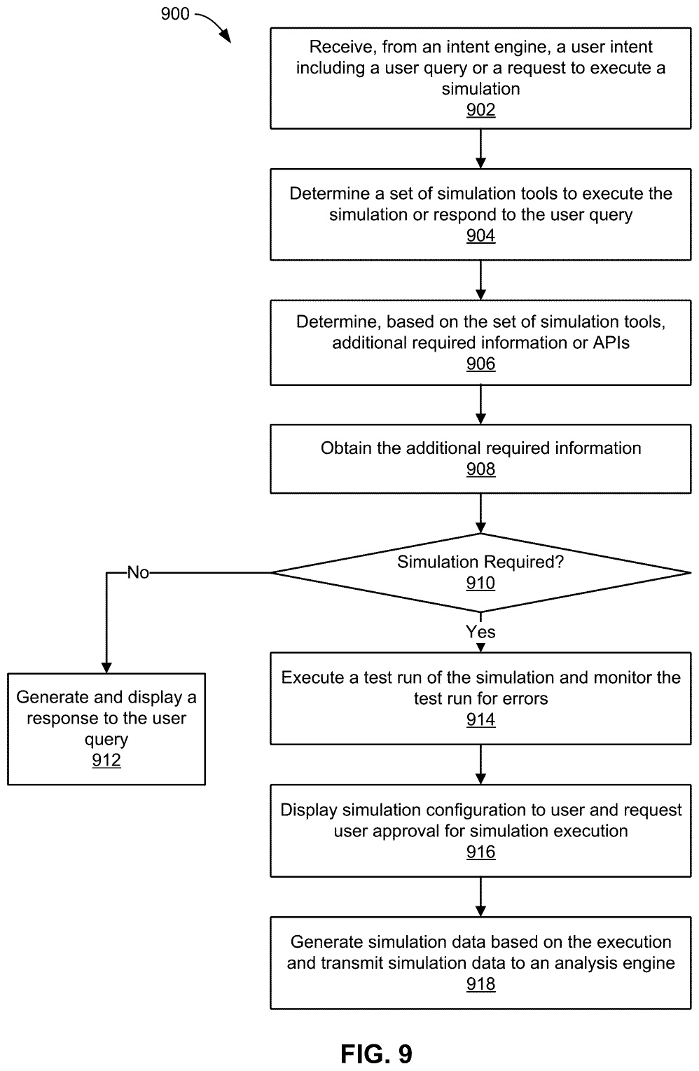

FIG. 9 is a flow diagram of method steps for configuring and executing one or more simulations in a simulation application, according to various embodiments. Although the method steps are described in conjunction with the systems of FIGS. 1-8, persons skilled in the art will understand that any system configured to perform the method steps in any order falls within the scope of the present disclosure.

As shown, a method 900 begins at operation 902, where simulation engine 124 receives a user intent from intent engine 122. For example, the user intent could include a query from a user regarding the capabilities or functionalities of simulation application 120, or the user intent could include a request to execute a simulation.

At operation 904, simulation engine 124 determines a set of simulation tools necessary to execute the requested simulation or otherwise respond to the user query. The set of simulation tools to execute the requested simulation can include one or more solvers or simulation models. In some embodiments, simulation engine 124 can use an embedding search, described above in conjunction with FIG. 8, to retrieve, from function schema database 770, one or more function schemas for the simulation tools associated with descriptions whose embeddings are similar to an embedding of the user intent.

At operation 906, simulation engine 124 determines, for each simulation tool in the set of simulation tools, additional information necessary for the execution of the simulation tool. In some embodiments, the function schemas retrieved at operation 904 includes parameters, necessary inputs, and/or variables for the simulation tools.

At operation 908, simulation engine 124 obtains the additional necessary information based on the function schemas. For example, simulation engine 124 could use language model 610 to generate natural language text asking for additional information from the user. As another example, simulation engine 124 could retrieve one or more APIs from function schema generator 700 or elsewhere.

At operation 910, simulation engine 124 determines whether the execution of a simulation is necessary. If the user intent received from intent engine 122 includes a general user query regarding the capabilities of simulation application 120 or a particular simulation tool, simulation engine 124 can determine that the execution of a simulation is not necessary. If the execution of a simulation is not necessary, the method proceeds to step 912, where simulation engine 124 generates and displays a response to the general user query.

At operation 914, simulation engine 124 executes a test run of the simulation. In some embodiments, simulation engine 124 can perform the test run on a limited quantity of data, for a limited period of time, and/or for a specified number of iterations. Simulation engine 124 monitors the execution of the test run and analyzes the execution to detect errors such as syntax errors, runtime errors, a rapidly diverging solution, an excessive consumption of system resources, and/or the like. If simulation engine 124 detects one or more errors, simulation engine 124 can attempt to diagnose and correct the error automatically, or simulation engine 124 can prompt the user to modify one or more parameters of the simulation to correct the error.

At operation 916, simulation engine 124 displays a finalized simulation configuration to the user and requests user approval for a full execution of the simulation.

Assuming that user approval is received, then at operation 918, simulation engine 124 executes the full simulation and generates simulation data. Simulation engine 124 stores the simulation data and transmits the simulation data to an analysis engine.

### Simulation Analysis

FIG. 10 is a more detailed illustration of analysis engine 126 of simulation application 120, according to various embodiments. As shown, analysis engine 126 includes, without limitation, a planner 1040, a tool generator 1045, a tool collector 1050, an executor 1060, an analyst module 1070, a display module 1080, and a report generator 1090. In operation, analysis engine 126 receives a user request for analysis of simulation data previously generated by simulation engine 124. Analysis engine 126 clarifies the user request, classifies the user request, and formulates a goal for analyzing the simulation data. Analysis engine 126 also collects and/or generates necessary tools for performing the requested analysis. Thereafter, analysis engine 126 executes the tools to generate analysis data, generates a textual summary of the analysis, performs a detailed examination of the analysis data, interprets the results, and displays a report of the results to the user.

In some embodiments, each of the components of analysis engine 126 can include or utilize the same or different multimodal large language models (not shown). In such cases, each multimodal large language model can process a combination of one or more of textual data, visual data, or multidimensional arrays. Although the output of each multimodal large language model is textual, each multimodal large language model can visualize simulation results via one or more functions for transforming textual data into graphical presentations.

Planner 1040 receives simulation data 1010 from simulation engine 124 and user input 1020. User input 1020 can include a request to analyze simulation data 1010. Planner 1040 includes a zero-shot classifier to classify the user request into one of a set of predefined classes. For example, planner 1040 can determine whether the user request is exploratory in nature, or whether the user request necessitates a definitive analysis. If planner 1040 determines that the user request is unclear, planner 1040 can prompt the user, via natural language text generated by a language model (e.g., language model 128), to provide additional information.

Planner 1040 generates, using a language model (e., language model 128), a goal for analyzing simulation data 1010 based on the determined class of the user request. The generated goal can include, e.g., a statistical review of simulation data 1010 or specific plots of simulation data 1010. If planner 1040 determines that the class of user request is exploratory, the generated goal can include data exploration, cluster analysis, outlier detection, and/or pattern recognition. If planner 1040 determines that the user request necessitates a definitive analysis, the generated goal can include specific statistical tests to validate a hypothesis, predictive modeling to forecast future trends, and/or the generation of custom plots to illustrate particular aspects of simulation data 1010. Planner 1040 transmits the generated goal to tool collector 1050 and tool generator 1045.

Tool collector 1050 receives the generated goal from planner 1040. Tool collector 1050 queries function schema generator 700 to determine the availability of analysis functions based on the generated goal. In some embodiments, the analysis functions can include visualizers, plotters, classifiers, or statistical analysis toolsets. Tool collector 1050 can determine the availability of analysis functions in any technically feasible manner in some embodiments. For example, in some embodiments, in a pre-step, tool collector 1050 can perform an embedding search to identify one or more most relevant schemas. Such a search returns the important schemas, which tool collector 150 can then provide to a language model (e.g., language model 128) to determine the necessary analysis functions. As another example, in some embodiments, the analysis functions can be included within a context that tool collector 150 provides to a language model (e.g., language model 128). In such cases, the language model can determine which functions to use based on in-context learning, leveraging the provided context to make accurate selections. As a further example, in some embodiments, tool collector 150 can employ heuristic techniques or rule-based approaches to identify and/or generate required analysis functions based on specific criteria or rules.

If tool collector 1050 determines that a needed analysis function is not available, analysis engine 126 generates the analysis function via tool generator 1045. As described above, tool generator 1045 can include or have access (e.g., via an API) to a multimodal large language model. Tool generator 1045 generates program source code for the required analysis function using the large language model and transmits a function schema for the generated analysis function to function schema generator 700 for storage and future use.

If tool generator 1045 is unable to generate program source code for a required analysis function, tool generator 1045 transmits an indication to planner 1040 that the required analysis function could not be generated. Planner 1040 adapts the generated goal to compensate for the unavailable analysis function. In some embodiments, planner 1040 can select an alternate analysis function to achieve the generated goal, or planner 1040 can remove the unavailable analysis function from the generated goal.

In some embodiments, tool generator 1045 can generate program code for analysis functions based on hardware available to simulation application 120. For example, if simulation application 120 utilizes a GPU, tool generator 1045 can reduce computational time requirements by generating program code adapted to parallel processing of large datasets. As another example, tool generator 1045 can generate program code adapted to more efficient use of available system memory or multi-threading capabilities.

Executor 1060 executes the analysis functions selected by tool collector 1050 and/or generated by tool generator 1045 and generates analysis data for subsequent analysis. In some embodiments, executor 1060 can include and/or use a language model (e.g., language model 128) to which available analysis functions are provided as an initial context. In such cases, the language model can invoke suitable analysis functions based on the user requested analysis that is also input into the language model, while providing appropriate parameters to the analysis functions. In some embodiments, executor 1060 also generates a textual summary of the analysis data generated by the executed analysis functions. If an analysis function executed by executor 1060 generates visual output such as images, videos, or multidimensional time-varying data, executor 1060 stores the visual output for subsequent retrieval and includes the location of the stored visual output in the textual summary. Executor 1060 also transmits the generated analysis data to analyst module 1070.

Analyst module 1070 produces a detailed analysis of the generated analysis data based on the user request, which can include trend analysis, forecasting, and/or pattern recognition. Then, analyst module 1070 transmits the analysis data to display module 1080 for presentation to the user.

Display module 1080 includes one or more post-processors and/or three-dimensional (3D) display modules that permit analysis data, including various visualizations, to be displayed to a user via, e.g., a UI. In some embodiments, display module 1080 receives user input 1020 specifying portions of multidimensional analysis data and displays the specified analysis data via the one or more post-processors or 3D display modules.

Report generator 1090 compiles a report of the analysis data based on the user request. In some embodiments, the report can include both textual results from the analysis data and visual data analytics generated by executor 1060.

FIG. 11 is a flow diagram of method steps for analyzing simulation data in a simulation application, according to various embodiments. Although the method steps are described in conjunction with the systems of FIGS. 1-10, persons skilled in the art will understand that any system configured to perform the method steps in any order falls within the scope of the present disclosure.

As shown, a method 1100 begins at operation 1102, where analysis engine 126 receives simulation data from simulation engine 124 and a user request for analysis of the simulation data.

At operation 1104, analysis engine 126 classifies the user request into one or a predefined set of classes. In some embodiments, analysis engine 126 can classify the user request via a zero-shot classifier. In some embodiments, the predefined set of classes can include an exploratory data analysis or one or more detailed analyses of the simulation data. If analysis engine 126 determines via the classification that the user request is unclear, analysis engine 126 can ask, via natural language text generated by a language model (e.g., language model 128), that the user input additional clarifying information.

In some embodiments, analysis engine 126 can generate an analysis goal based on the user input and the zero-shot classification. If analysis engine 126 determines that the class of user request is exploratory, the generated analysis goal can include data exploration, cluster analysis, outlier detection, and/or pattern recognition. If planner 1040 determines that the user request necessitates a definitive analysis, the generated goal can include specific statistical tests to validate a hypothesis, predictive modeling to forecast future trends, and/or the generation of custom plots to illustrate particular aspects of simulation data 1010.

At operation 1106, analysis engine 126 determines and/or generates analysis functions needed to satisfy the generated analysis goal. As described, the analysis functions can be determined and/or generated in any technically feasible manner in some embodiments. For example, in some embodiments, in a pre-step, analysis engine 126 (and, specifically, tool collector 1050 of analysis engine 126) can perform an embedding search to identify one or more most relevant schemas. Such a search returns the important schemas, which analysis engine 126 can then provide to a language model (e.g., language model 128) to determine the necessary analysis functions. As another example, in some embodiments, the analysis functions can be included within a context that analysis engine 126 provides to a language model (e.g., language model 128). In such cases, the language model can determine which functions to use based on in-context learning. As a further example, in some embodiments, analysis engine 126 can employ heuristic techniques or rule-based approaches to identify and/or generate required analysis functions based on specific criteria or rules. In addition, in some embodiments, analysis engine 126 can ask a language model (e.g., language model 128) to generate program code for any required analysis functions that are not available.

At operation 1108, analysis engine 126 executes the determined or generated analysis functions based on the simulation data to generate analysis data. In some embodiments, analysis engine 126 includes and/or uses a language model to which available analysis functions are provided as an initial context. In such cases, the language model can invoke the analysis functions determined or generated at operation 1106 while providing appropriate parameters to the analysis functions. In some embodiments, the analysis data can include textual information as well as graphical or video representations of data.

At operation 1110, analysis engine 126 generates a textual summary of the analysis data generated by the executed analysis functions. If an analysis function executed by analysis engine 126 generates visual output such as images, videos, and/or multidimensional time-varying data, analysis engine 126 stores the visual output for subsequent retrieval and can include the location of the stored visual output in the textual summary.

At operation 1112, analysis engine 126 displays the textual summary to the user. The textual summary can be displayed in any technically feasible manner in some embodiments. In some embodiments, analysis engine 126 can include one or more post-processors or three-dimensional (3D) applications. In such cases, analysis engine 126 can receive interactive user input specifying portions of the multidimensional analysis data and display the specified analysis data via the one or more post-processors or 3D applications.

At operation 1114, analysis engine 126 generates and displays a report to the user. In some embodiments, the report can include both textual results from the analysis data and visual data analytics. Based on the user request, analysis engine 126 can generate interpretations and implications of the analysis. For example, if the user request includes a request for a trend analysis or forecast, the report can include a trend or a specific forecasted future value. In some embodiments, the report can also include recommendations that are generated via one or more analysis functions.

In sum, the disclosed systems and techniques provide a simulation application that enables the description, configuration, execution, and analysis of computer-based simulations of physical components or systems via one or more language models and a conversational user interface. In some embodiments, the simulation application receives a natural-language simulation request from a user and determines the user intent for a simulation. The simulation application then selects appropriate tools, functions, and simulation models; executes the simulation models; and analyzes data generated during simulation. The simulation application can further generate summaries and reports based on the simulation data and an analysis request.

In operation, the simulation application receives a user input from a user via a conversational user interface that utilizes a language model, such as a large language model. An intent engine included in the simulation application determines a user intent from the user input. The intent engine can map the user input or a simplification of the user input to one of a number of classes of intents using a zero-shot classification technique, a predefined data structure that specifies definite options for the classes of intents, a fine-tuned language model that outputs classes of intents, and/or the like.

A simulation engine included in the simulation application configures one or more solvers and/or simulation models based on the simulation request and one or more predefined data structures that specify information necessary for executing the solver(s) and/or simulation model(s). The simulation engine can also automatically retrieve or ask, via natural-language text generated by the language model, the user to provide the necessary information for configuring and executing the solver(s) and/or simulation model(s), as indicated by the predefined data structure(s). The simulation engine then executes the solver(s) and/or simulation model(s) to generate simulation data.

An analysis engine included in the simulation application receives an analysis request from the user. If the analysis request is unclear, the analysis engine can ask the user for further information using natural language text generated by the language model. The analysis engine determines whether the nature of the analysis request is exploratory or if the analysis request necessitates a definitive analysis, and the analysis engine generates an analysis plan. If the analysis request is exploratory in nature, the analysis plan can include exploratory data exploration, cluster analysis, outlier detection, and/or pattern recognition. If the analysis request requires a definitive analysis, the generated analysis plan can include specific statistical tests to validate one or more hypotheses, predictive modeling to anticipate future trends, and/or designing detailed, specific visual plots to illustrate specific points. The analysis engine verifies the availability of essential functions such as visualizers, plotters, classifiers, and/or statistical analysis toolsets. If a required function or toolset is missing, the analysis engine employs the language model to generate program computer code for implementing the missing function or toolset.

Thereafter, the analysis engine executes the analysis plan and generates a textual summary of the analysis results. If the analysis results include visual elements such as videos, plots, and/or time-varying data, the analysis engine stores the visual elements for later retrieval and integrates the location of the visual elements into the textual summary. The analysis engine can further generate a detailed report based on the analysis results and the analysis request. The detailed report can include conclusions associated with the analysis results or implications of the analysis results, based on the analysis request. The detailed report can further incorporate both the textual summary and any stored visual elements.

One technical advantage of the disclosed techniques relative to the prior art is that the disclosed techniques provide for interactive, natural-language interaction between a user and various components of a simulation application. The disclosed techniques iteratively engage with a user to determine the intent of a user request. The techniques further interact with the user via natural language to configure one or more simulation models and/or solvers prior to performing requested simulations. The techniques continue to interact with the user during the analysis of simulation data and can generate one or more reports based on the simulation data. These technical advantages provide one or more technological improvements over prior art approaches.
1. In some embodiments, a computer-implemented method for determining user intent comprises receiving user input that comprises first natural language text, performing one or more operations to map the user input to one or more classes of intents included in a plurality of classes of intents, and responsive to determining that the user input does not map to any class of intents, generating, via a first trained language model, second natural language text requesting additional user input.
2. The computer-implemented method of clause 1, wherein performing one or more operations to map the user input to the one or more classes of intents comprises generating, via a second trained language model, a simplified input based on the user input, and mapping, via a zero-shot classification model, the simplified input to the one or more classes of intents.
3. The computer-implemented method of clauses 1 or 2, wherein mapping, via the zero-shot classification model, the simplified input to the one or more classes of intents comprises comparing a vector embedding of the simplified input with vector embeddings associated with each class of intents included in the plurality of classes of intents.
4. The computer-implemented method of any of clauses 1-3, wherein performing one or more operations to map the user input to the one or more classes of intents comprises generating, via a second trained language model, a simplified input based on the user input, and mapping, via a chain-of-thought technique that uses a third trained language model, the simplified input to the one or more classes of intents.
5. The computer-implemented method of any of clauses 1-4, wherein performing one or more operations to map the user input to the one or more classes of intents comprises determining that the user input corresponds to the at least one class included in a predefined data structure.
6. The computer-implemented method of any of clauses 1-5, wherein performing one or more operations to map the user input to the one or more classes of intents comprises mapping, via a second trained language model, the user input to the one or more classes of intents, wherein the second trained language model is trained to output the plurality of classes of intents.
7. The computer-implemented method of any of clauses 1-6, further comprising determining that the user input does not map to any class of intents based on an uncertainty associated with the mapping of the user input to the one or more classes of intents.
8. The computer-implemented method of any of clauses 1-7, further comprising performing one or more operations to configure and execute a simulation based on the one or more classes of intents.
9. The computer-implemented method of any of clauses 1-8, further comprising receiving the additional user input, and performing one or more operations to map the additional user input to one or more classes of intents included in a plurality of classes of intents.
10. The computer-implemented method of any of clauses 1-9, further comprising displaying the second natural language text to a user via a user interface.
11. In some embodiments, one or more non-transitory computer-readable storage media include instructions that, when executed by at least one processor, cause the at least one processor to perform steps for determining user intent, the steps comprising receiving user input that comprises first natural language text, performing one or more operations to map the user input to one or more classes of intents included in a plurality of classes of intents, and responsive to determining that the user input does not map to any class of intents, generating, via a trained language model, second natural language text requesting additional user input.
12. The one or more non-transitory computer-readable storage media of clause 11, wherein performing one or more operations to map the user input to the one or more classes of intents comprises generating, via the trained language model, a simplified input based on the user input, and mapping, via a zero-shot classification model, the simplified input to the one or more classes of intents.
13. The one or more non-transitory computer-readable storage media of clauses 11 or 12, wherein performing one or more operations to map the user input to the one or more classes of intents comprises generating, via the trained language model, a simplified input based on the user input, and mapping, via a chain-of-thought technique that uses the trained language model, the simplified input to the one or more classes of intents.
14. The one or more non-transitory computer-readable storage media of any of clauses 11-13, wherein performing one or more operations to map the user input to the one or more classes of intents comprises determining that the user input corresponds to the at least one class included in a predefined data structure.
15. The one or more non-transitory computer-readable storage media of any of clauses 11-14, wherein performing one or more operations to map the user input to the one or more classes of intents comprises mapping, via another trained language model, the user input to the one or more classes of intents, wherein the second trained language model is trained to output the plurality of classes of intents.
16. The one or more non-transitory computer-readable storage media of any of clauses 11-15, wherein the instructions, when executed by the at least one processor, further cause the at least one processor to perform the step of determining that the user input does not map to any class of intents based on an uncertainty associated with the mapping of the user input to the one or more classes of intents.
17. The one or more non-transitory computer-readable storage media of any of clauses 11-16, wherein the instructions, when executed by the at least one processor, further cause the at least one processor to perform the step of performing one or more operations to configure and execute a simulation based on the one or more classes of intents.
18. The one or more non-transitory computer-readable storage media of any of clauses 11-17, wherein the instructions, when executed by the at least one processor, further cause the at least one processor to perform steps comprising receiving the additional user input, and performing one or more operations to map the additional user input to the one or more classes of intents included in a plurality of classes of intents.
19. The one or more non-transitory computer-readable storage media of any of clauses 11-18, wherein the instructions, when executed by the at least one processor, further cause the at least one processor to perform the step of displaying the second natural language text to a user via a user interface.
20. In some embodiments, a system comprises one or more memories storing instructions, and one or more processors that are coupled to the one or more memories and, when executing the instructions, are configured to receive user input that comprises first natural language text, perform one or more operations to map the user input to one or more classes of intents included in a plurality of classes of intents, and responsive to determining that the user input does not map to any class of intents, generate, via a first trained language model, second natural language text requesting additional user input.
1. In some embodiments, a computer-implemented method for performing a simulation comprises selecting a first data structure from a plurality of data structures based on a user input, responsive to determining that one or more values for one or more parameters specified in the first data structure cannot be determined based on the user input, generating, via a trained language model, first natural language text requesting additional user input, and performing, based on the additional user input, a simulation to generate simulation data.
2. The computer-implemented method of clause 1, wherein the first data structure is selected based on one or more comparisons of a first embedding associated with the user input with a plurality of embeddings associated with the plurality of data structures.
3. The computer-implemented method of clauses 1 or 2, further comprising generating the plurality of embeddings associated with the plurality of data structures based on a plurality of text descriptions associated with the plurality of data structures.
4. The computer-implemented method of any of clauses 1-3, further comprising performing one or more operations to determine one or more values for the one or more parameters based on the additional user input.
5. The computer-implemented method of any of clauses 1-4, further comprising determining an intent based on the user input, wherein the first data structure is selected based on the intent.
6. The computer-implemented method of any of clauses 1-5, further comprising performing a test of the simulation based on the additional user input, and responsive to one or more errors during the test, generating, via the trained language model, second natural language text requesting additional user input.
7. The computer-implemented method of any of clauses 1-6, further comprising generating the first data structure based on information associated with the simulation and a predefined template.
8. The computer-implemented method of any of clauses 1-7, wherein performing the simulation comprises executing at least one of a solver or a simulation model.
9. The computer-implemented method of any of clauses 1-8, further comprising displaying information associated with the simulation based on the user input.
10. The computer-implemented method of any of clauses 1-9, further comprising displaying a configuration of the simulation to a user, and receiving approval from the user to perform the simulation based on the configuration.
11. In some embodiments, one or more non-transitory computer-readable storage media include instructions that, when executed by at least one processor, cause the at least one processor to perform steps for performing a simulation, the steps comprising selecting a first data structure from a plurality of data structures based on a user input, responsive to determining that one or more values for one or more parameters specified in the first data structure cannot be determined based on the user input, generating, via a trained language model, first natural language text requesting additional user input, and performing, based on the additional user input, a simulation to generate simulation data.
12. The one or more non-transitory computer-readable storage media of clause 11, wherein the first data structure is selected based on one or more comparisons of a first embedding associated with the user input with a plurality of embeddings associated with the plurality of data structures.
13. The one or more non-transitory computer-readable storage media of clauses 11 or 12, wherein the instructions, when executed by the at least one processor, further cause the at least one processor to perform the step of generating the plurality of embeddings associated with the plurality of data structures based on a plurality of text descriptions associated with the plurality of data structures.
14. The one or more non-transitory computer-readable storage media of any of clauses 11-13, wherein the instructions, when executed by the at least one processor, further cause the at least one processor to perform the step of performing one or more operations to retrieve at least one of information or an application programming interface (API) based on the first data structure.
15. The one or more non-transitory computer-readable storage media of any of clauses 11-14, wherein the instructions, when executed by the at least one processor, further cause the at least one processor to perform steps comprising performing a test of the simulation based on the additional user input, and responsive to one or more errors during the test, generating, via the trained language model, second natural language text requesting additional user input.
16. The one or more non-transitory computer-readable storage media of any of clauses 11-15, wherein the instructions, when executed by the at least one processor, further cause the at least one processor to perform the step of generating the first data structure based on information associated with the simulation and a predefined template.
17. The one or more non-transitory computer-readable storage media of any of clauses 11-16, wherein the trained language model comprises a trained large language model.
18. The one or more non-transitory computer-readable storage media of any of clauses 11-17, wherein the instructions, when executed by the at least one processor, further cause the at least one processor to perform steps comprising displaying a configuration of the simulation to a user, and receiving approval from the user to perform the simulation based on the configuration.
19. The one or more non-transitory computer-readable storage media of any of clauses 11-18, wherein the instructions, when executed by the at least one processor, further cause the at least one processor to perform the step of performing one or more operations to analyze the simulation data to generate analysis data.
20. In some embodiments, a system comprises one or more memories storing instructions, and one or more processors that are coupled to the one or more memories and, when executing the instructions, are configured to selecting a first data structure from a plurality of data structures based on a user input, responsive to determining that one or more values for one or more parameters specified in the first data structure cannot be determined based on the user input, generating, via a trained language model, first natural language text requesting additional user input, and performing, based on the additional user input, a simulation to generate simulation data.
1. In some embodiments, a computer-implemented method for analyzing data comprises determining, based on a first trained language model and a user request, one or more first functions, and executing the one or more first functions based on the data to generate first analysis data.
2. The computer-implemented method of clause 1, further comprising performing one or more operations to generate, based on a second trained language model and the user request, one or more second functions, and executing the one or more second functions based on the data to generate second analysis data.
3. The computer-implemented method of clauses 1 or 2, wherein performing the one or more operations to generate the one or more second functions comprises requesting the second trained language model to generate program code for the one or more second functions.
4. The computer-implemented method of any of clauses 1-3, wherein information about the one or more first functions is included in a context that is input into the first trained language model.
5. The computer-implemented method of any of clauses 1-4, further comprising generating at least one of a summary or a report based on the first analysis data, and displaying the at least one of the summary or the report to a user.
6. The computer-implemented method of any of clauses 1-5, wherein the data includes simulation data, and the method further comprises performing a simulation to generate the simulation data.
7. The computer-implemented method of any of clauses 1-6, wherein executing the one or more first function comprises configuring, via a second trained language model, execution of the one or more first functions.
8. The computer-implemented method of any of clauses 1-7, wherein determining the one or more first functions comprises determining one or more goals associated with the user request, and determining the one or more first functions based on the one or more goals.
9. The computer-implemented method of any of clauses 1-8, wherein determining the one or more goals comprises performing one or more zero-shot classification operations.
10. The computer-implemented method of any of clauses 1-9, wherein the one or more goals include at least one of data exploration, cluster analysis, outlier detection, pattern recognition, statistical testing, predictive modeling, or generating one or more visualizations.
11. In some embodiments, one or more non-transitory computer-readable storage media include instructions that, when executed by at least one processor, cause the at least one processor to perform steps for analyzing data, the steps comprising determining, based on a trained language model and a user request, one or more first functions, and executing the one or more first functions based on the data to generate first analysis data.
12. The one or more non-transitory computer-readable storage media of clause 11, wherein the instructions, when executed by the at least one processor, further cause the at least one processor to perform steps comprising performing one or more operations to generate, based on the trained language model and the user request, one or more second functions, and executing the one or more second functions based on the data to generate second analysis data.
13. The one or more non-transitory computer-readable storage media of clauses 11 or 12, wherein performing the one or more operations to generate the one or more second functions comprises requesting the trained language model to generate program code for the one or more second functions.
14. The one or more non-transitory computer-readable storage media of any of clauses 11-13, wherein information about the one or more first functions is included in a context that is input into the trained language model.
15. The one or more non-transitory computer-readable storage media of any of clauses 11-14, wherein the instructions, when executed by the at least one processor, further cause the at least one processor to perform steps comprising generating at least one of a summary or a report based on the first analysis data, and displaying the at least one of the summary or the report to a user.
16. The one or more non-transitory computer-readable storage media of any of clauses 11-15, wherein the data includes simulation data, and the instructions, when executed by the at least one processor, further cause the at least one processor to perform the step of performing a simulation to generate the simulation data.
17. The one or more non-transitory computer-readable storage media of any of clauses 11-16, wherein executing the one or more first function comprises configuring, via the trained language model, execution of the one or more first functions.
18. The one or more non-transitory computer-readable storage media of any of clauses 11-17, wherein determining the one or more first functions comprises determining one or more goals associated with the user request, and determining the one or more first functions based on the one or more goals.
19. The one or more non-transitory computer-readable storage media of any of clauses 11-18, wherein the first analysis data includes at least one of one or more images, one or more videos, or multidimensional time-varying data.
20. In some embodiments, a system comprises one or more memories storing instructions, and one or more processors that are coupled to the one or more memories and, when executing the instructions, are configured to determine, based on a first trained language model and a user request, one or more first functions, and execute the one or more first functions based on data to generate first analysis data.

Any and all combinations of any of the claim elements recited in any of the claims and/or any elements described in this application, in any fashion, fall within the contemplated scope of the present invention and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for analyzing data, the method comprising:
determining, based on a first trained language model and a user request, one or more first functions; and
executing the one or more first functions based on the data to generate first analysis data.

2. The computer-implemented method of claim 1, further comprising:
performing one or more operations to generate, based on a second trained language model and the user request, one or more second functions; and
executing the one or more second functions based on the data to generate second analysis data.

3. The computer-implemented method of claim 2, wherein performing the one or more operations to generate the one or more second functions comprises requesting the second trained language model to generate program code for the one or more second functions.

4. The computer-implemented method of claim 1, wherein information about the one or more first functions is included in a context that is input into the first trained language model.

5. The computer-implemented method of claim 1, further comprising:
generating at least one of a summary or a report based on the first analysis data; and
displaying the at least one of the summary or the report to a user.

6. The computer-implemented method of claim 1, wherein the data includes simulation data, and the method further comprises performing a simulation to generate the simulation data.

7. The computer-implemented method of claim 1, wherein executing the one or more first function comprises configuring, via a second trained language model, execution of the one or more first functions.

8. The computer-implemented method of claim 1, wherein determining the one or more first functions comprises:
determining one or more goals associated with the user request; and
determining the one or more first functions based on the one or more goals.

9. The computer-implemented method of claim 8, wherein determining the one or more goals comprises performing one or more zero-shot classification operations.

10. The computer-implemented method of claim 8, wherein the one or more goals include at least one of data exploration, cluster analysis, outlier detection, pattern recognition, statistical testing, predictive modeling, or generating one or more visualizations.

11. One or more non-transitory computer-readable storage media including instructions that, when executed by at least one processor, cause the at least one processor to perform steps for analyzing data, the steps comprising:
determining, based on a trained language model and a user request, one or more first functions; and
executing the one or more first functions based on the data to generate first analysis data.

12. The one or more non-transitory computer-readable storage media of claim 11, wherein the instructions, when executed by the at least one processor, further cause the at least one processor to perform steps comprising:
performing one or more operations to generate, based on the trained language model and the user request, one or more second functions; and
executing the one or more second functions based on the data to generate second analysis data.

13. The one or more non-transitory computer-readable storage media of claim 12, wherein performing the one or more operations to generate the one or more second functions comprises requesting the trained language model to generate program code for the one or more second functions.

14. The one or more non-transitory computer-readable storage media of claim 11, wherein information about the one or more first functions is included in a context that is input into the trained language model.

15. The one or more non-transitory computer-readable storage media of claim 11, wherein the instructions, when executed by the at least one processor, further cause the at least one processor to perform steps comprising:
generating at least one of a summary or a report based on the first analysis data; and
displaying the at least one of the summary or the report to a user.

16. The one or more non-transitory computer-readable storage media of claim 11, wherein the data includes simulation data, and the instructions, when executed by the at least one processor, further cause the at least one processor to perform the step of performing a simulation to generate the simulation data.

17. The one or more non-transitory computer-readable storage media of claim 11, wherein executing the one or more first function comprises configuring, via the trained language model, execution of the one or more first functions.

18. The one or more non-transitory computer-readable storage media of claim 11, wherein determining the one or more first functions comprises:
determining one or more goals associated with the user request; and
determining the one or more first functions based on the one or more goals.

19. The one or more non-transitory computer-readable storage media of claim 11, wherein the first analysis data includes at least one of one or more images, one or more videos, or multidimensional time-varying data.

20. A system, comprising:
one or more memories storing instructions; and
one or more processors that are coupled to the one or more memories and, when executing the instructions, are configured to:
determine, based on a first trained language model and a user request, one or more first functions, and
execute the one or more first functions based on data to generate first analysis data.
